(19) United States
(12) Patent Application Publication
(10) Pub. No.: US 2026/0150650 A1
(43) Pub. Date: May 28, 2026

(54) SEMICONDUCTOR DIE HAVING A CONDUCTIVE BRIDGE COMPRISING A METAL VIA COUPLING TWO ADJACENT METAL INTERCONNECTS IN A SINGLE METALLIZATION LAYER TO ADDRESS TIGER TOOTH DEFECTS

(71) Applicant: QUALCOMM Incorporated, San Diego, CA (US)

(72) Inventors: Junjing Bao, San Diego, CA (US); Hyunwoo Park, San Diego, CA (US); Haining Yang, San Diego, CA (US)

(21) Appl. No.: 18/958,090

(22) Filed: Nov. 25, 2024

(51) Int. Cl. H10W 20/43; H10W 20/00; H10W 20/42; H10W 20/48

(52) U.S. Cl. CPC H10W 20/43; H10W 20/01; H10W 20/42; H10W 20/48

(57) ABSTRACT

Aspects disclosed include a semiconductor die including a conductive bridge comprising a metal via coupling two adjacent metal interconnects in a single metal layer to address tiger tooth defects. The die includes a first dielectric layer in which the two adjacent metal interconnects are formed. The metal via is coupled to the top surface of the two adjacent metal interconnects and extends over the top surface of the first dielectric layer between the two adjacent metal interconnects. The conductive bridge includes a portion of the two adjacent metal interconnects coupled to the bottom surface of the metal via and a dielectric protection layer between the bottom surface of the metal via and the top surface of the first dielectric layer and co-extensive with the bottom surface of the metal via. The two adjacent metal interconnects do not have any intervening metal interconnects between them.

### TECHNICAL FIELD

The field of the disclosure relates to a structure and fabrication of a metal via in a semiconductor die in a back end of line process.

### BACKGROUND

Integrated circuits (ICs) are the cornerstone of electronic devices. ICs are packaged in an IC package, also called a “semiconductor package” or “chip package.” The IC package includes one or more semiconductor dice (“dies” or “dice”) as an IC(s) that is mounted on and electrically coupled to a package substrate to provide physical support and an electrical interface to the die(s). The package substrate also includes one or more metallization layers that include metal interconnects (e.g., metal traces, metal lines) with vertical interconnect accesses (vias) coupling the metal interconnects together between adjacent metallization layers to provide electrical interfaces between the die(s). The package substrate also includes an outer metallization layer that includes metal interconnects coupled to external metal interconnects (e.g., ball grid array (BGA) interconnects) to provide an external interface between the die(s) in the IC package. The external metal interconnects can also be coupled (e.g., soldered) to traces in a printed circuit board (PCB) to attach the package to the PCB and interface its die(s) with the circuitry of the PCB.

The die(s) also includes one or more metallization layers that include a metal layer formed in a dielectric layer. Metal interconnects (also referred to as metal traces, metal lines, metal tracks) are formed in the metal layer. One or more metallization layers include another dielectric layer, also referred to as a via layer, which includes one or more vias which couple one or more metal interconnects in one metallization layer with one or more metal interconnects in an adjacent metallization layer. The one or more metallization layers are fabricated in the die(s) utilizing a back end of line (BEOL) process to form a BEOL interconnect structure. An outer metallization layer of the one or more metallization layers includes metal interconnects fabricated during the BEOL process (e.g., pads). The die(s) also includes die interconnects (e.g., balls or pillars) which are supported by metal pads in the outer metallization layer and electrically couple the metal interconnects in the die(s) to the metal interconnects exposed in the outer metallization layer (e.g., pads) of the package substrate or another die.

The die(s) also includes a front-end-of-line (FEOL) structure upon which the BEOL interconnect structure formed is disposed. The FEOL structure includes field-effect transistors (FETs) and a contact layer to couple to nodes of the FETs.

### SUMMARY

Aspects disclosed in the detailed description include a semiconductor die (“die”) having a conductive bridge comprising a metal via coupling two adjacent metal interconnects in a single metal layer to address tiger tooth defects. The die includes a first dielectric layer in which the two adjacent metal interconnects are formed. The metal via is coupled to the top surface of the two adjacent metal interconnects and extends over the top surface of the first dielectric layer between the two adjacent metal interconnects. The conductive bridge includes a portion of the two adjacent metal interconnects coupled to the bottom surface of the metal via and a dielectric protection layer between the bottom surface of the metal via and the top surface of the first dielectric layer and co-extensive with the bottom surface of the metal via. The two adjacent metal interconnects do not have any intervening metal interconnects between them.

Conventional fabrication pitch requirements between adjacent vias are currently greater than the pitch requirements between adjacent metal interconnects. As a result, two adjacent metal interconnects in the same metal layer cannot be coupled by a via, thus the overall size of a standard cell in the die is limited by the conventional pitch requirements between adjacent vias. The reason for the larger conventional pitch requirements is to ensure that the existing fabrication tools do not misalign a via with an underlying metal interconnect during a single ultraviolet etching process. If a via is misaligned, over etching the via may cause a tiger tooth defect. Tiger tooth defects may result in a dielectric breakdown and potential circuit failures between adjacent metal interconnects that are not intended to be coupled. The conductive bridge with the dielectric protection layer between the bottom surface of the metal via and the first top surface of the first dielectric layer and that is co-extensive with the bottom surface of the metal via advantageously prevents over etching of a via when a via is not perfectly aligned with an underlying metal interconnect and, thus, addresses tiger tooth defects. Consequently, the dielectric protection layer between the bottom surface of the metal via and the first top surface of the first dielectric layer enables coupling two adjacent metal interconnects in the same metal layer thus reducing the size of a standard cell in a die by limiting its size by the smaller pitch requirements of adjacent metal interconnects.

In this regard in one aspect, a semiconductor die is disclosed. The semiconductor die comprises a first metallization layer and a conductive bridge. The first metallization layer comprises a first dielectric layer extending in a horizontal direction and having a first top surface and a first metal layer extending in the horizontal direction and formed in the first dielectric layer. The first metal layer comprises a plurality of adjacent metal interconnects having a second top surface. The conductive bridge comprises a metal via having a bottom surface. The metal via is coupled to the second top surface of the plurality of adjacent metal interconnects and extends over the first top surface of the first dielectric layer between the plurality of adjacent metal interconnects. The conductive bridge also comprises a portion of the plurality of adjacent metal interconnects coupled to the bottom surface of the metal via and a dielectric protection layer between the bottom surface of the metal via and the first top surface of the first dielectric layer and co-extensive with the bottom surface of the metal via between the plurality of adjacent metal interconnects.

In another aspect, a method for fabricating an electronic device is disclosed. The method comprises forming a first metallization layer. Forming the first metallization layer comprises forming a first dielectric layer extending in a horizontal direction and having a first top surface and forming a first metal layer extending in the horizontal direction in the first dielectric layer. Forming the first metal layer comprises forming a plurality of adjacent metal interconnects having a second top surface. The method further comprises forming a conductive bridge. Forming the conductive bridge further comprises forming a metal via having a bottom surface. Forming the metal via further comprises extending the metal via over the first top surface of the first dielectric layer between the plurality of adjacent metal interconnects and coupling the metal via to the second top surface of the plurality of adjacent metal interconnects. Forming the conductive bridge further comprises coupling the bottom surface of the metal via to a portion of the plurality of adjacent metal interconnects and forming a dielectric protection layer between the bottom surface of the metal via and the first top surface of the first dielectric layer and co-extensive with the bottom surface of the metal via between the plurality of adjacent metal interconnects.

### BRIEF DESCRIPTION OF THE DRAWINGS

FIG. 1A is a side view of an integrated circuit (IC) that includes a portion of a die, the die including an exemplary conductive bridge comprising a metal via coupling two adjacent metal interconnects in a single metallization layer to address tiger tooth defects;

FIG. 1B is close-up view of the exemplary conductive bridge in FIG. 1A along cutout A;

FIG. 1C is a top-down perspective view of cutout B of the exemplary conductive bridge in FIG. 1A;

FIG. 2A is a side view of an integrated circuit (IC) that includes a portion of a die, the die including another exemplary conductive bridge comprising a metal via coupling three adjacent metal interconnects in a single metallization layer to address tiger tooth defects;

FIG. 2B is a close-up view of the exemplary conductive bridge in FIG. 2A along cutout C;

FIG. 2C is a top-down perspective view of cutout D of the exemplary conductive bridge in FIG. 2A;

FIGS. 3A-3B is a flowchart illustrating an exemplary fabrication process of fabricating a conductive bridge such as the conductive bridges described in FIGS. 1A-1C and 2A-2C, in a back end of line (BEOL) process wherein the conductive bridge comprises a metal via coupling two adjacent metal interconnects in a single layer to address tiger tooth defects, including, but not limited to, the conductive bridges in FIGS. 1A-1C and 2A-2C;

FIGS. 4A-4E is a flowchart illustrating another exemplary fabrication process of fabricating a conductive bridge such as the conductive bridges described in FIGS. 1A-1C and 2A-2C, in a BEOL process wherein the conductive bridge comprises a metal via coupling two adjacent metal interconnects in a single layer to address tiger tooth defects, including, but not limited to, the conductive bridges in FIGS. 1A-1C and 2A-2C;

FIGS. 5A-5M are exemplary fabrication stages during fabrication of the IC package according to the fabrication process in FIGS. 4A-4E;

FIG. 6 is a block diagram of an exemplary processor-based system that can include components deployed in a die, wherein the die includes an exemplary conductive bridge comprising a metal via coupling two adjacent metal interconnects in a single metallization layer to address tiger tooth defects, including, but not limited to, the conductive bridges in FIGS. 1A-1C and 2A-2C and according to the exemplary fabrication processes in FIGS. 3 and 4A-4E; and

FIG. 7 is a block diagram of an exemplary wireless communications device that includes radio-frequency (RF) components formed from one or more dies, wherein any of the dies includes an exemplary conductive bridge comprising a metal via coupling two adjacent metal interconnects in a single metallization layer to address tiger tooth defects, including, but not limited to, the conductive bridges in FIGS. 1A-1C and 2A-2C and according to the exemplary fabrication processes in FIGS. 3 and 4A-4E.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

It should be understood that the terms “first,” “second,” “third,” etc., where used herein, are relative terms and are not meant to limit or imply a strict orientation. It should also be understood that that the terms “top,” “upper,” “above,” and “bottom,” “lower,” “below,” where used herein, are relative terms and are not meant to limit or imply a strict orientation. A “top” or “upper” or “above” referenced element does not always need to be oriented to be above a “bottom,” or “lower,” or “below” referenced element with respect to ground, and vice versa. An element referenced as “top,” “upper,” “above,” or “bottom,” “lower,” “below,” may be on top or bottom relative to that example only and the particular illustrated example. For example, if a particular object that is discussed as at “top,” or “upper” or “above” another object, and such particular object is flipped 180 degrees, then such particular object would then be oriented as at “bottom,” or “lower” or “below” such other object.

Further, an object being “adjacent” as discussed herein relates to an object being beside or next to another stated object. Adjacent objects may not be directly physically coupled to each other. An object can be directly adjacent to another object which means that such objects are directly beside or next to the other object without another object or layer being intervening or disposed between the directly adjacent objects. An object can be indirectly or non-directly adjacent to another object which means that such objects are not directly beside or directly next to each other, but there is an intervening object or layer disposed between the non-directly adjacent objects.

Aspects disclosed in the detailed description include a semiconductor die (“die”) having a conductive bridge comprising a metal via coupling two adjacent metal interconnects in a single metallization layer to address tiger tooth defects. The die includes a first dielectric layer in which the two adjacent metal interconnects are formed. The metal via is coupled to the top surface of the two adjacent metal interconnects and extends over the top surface of the first dielectric layer between the two adjacent metal interconnects. The conductive bridge includes a portion of the two adjacent metal interconnects coupled to the bottom surface of the metal via and a dielectric protection layer between the bottom surface of the metal via and the top surface of the first dielectric layer and co-extensive with the bottom surface of the metal via. The two adjacent metal interconnects do not have any intervening metal interconnects between them.

Conventional fabrication pitch requirements between adjacent vias are currently greater than the pitch requirements between adjacent metal interconnects. As a result, two adjacent metal interconnects in the same metal layer cannot be coupled by a via, thus the overall size of a standard cell in the die is limited by the conventional pitch requirements between adjacent vias. The reason for the larger conventional pitch requirements is to ensure that the existing fabrication tools do not misalign a via with an underlying metal interconnect during a single ultraviolet etching process. If a via is misaligned, over etching the via may cause a tiger tooth defect. Tiger tooth defects may result in a dielectric breakdown and potential circuit failures between adjacent metal interconnects that are not intended to be coupled. The conductive bridge with the dielectric protection layer between the bottom surface of the metal via and the first top surface of the first dielectric layer and that is co-extensive with the bottom surface of the metal via advantageously prevents over etching of a via when a via is not perfectly aligned with an underlying metal interconnect and, thus, addresses tiger tooth defects. Consequently, the dielectric protection layer between the bottom surface of the metal via and the first top surface of the first dielectric layer enables coupling two adjacent metal interconnects in the same metal layer thus reducing the size of a standard cell in a die by limiting its size by the smaller pitch requirements of adjacent metal interconnects.

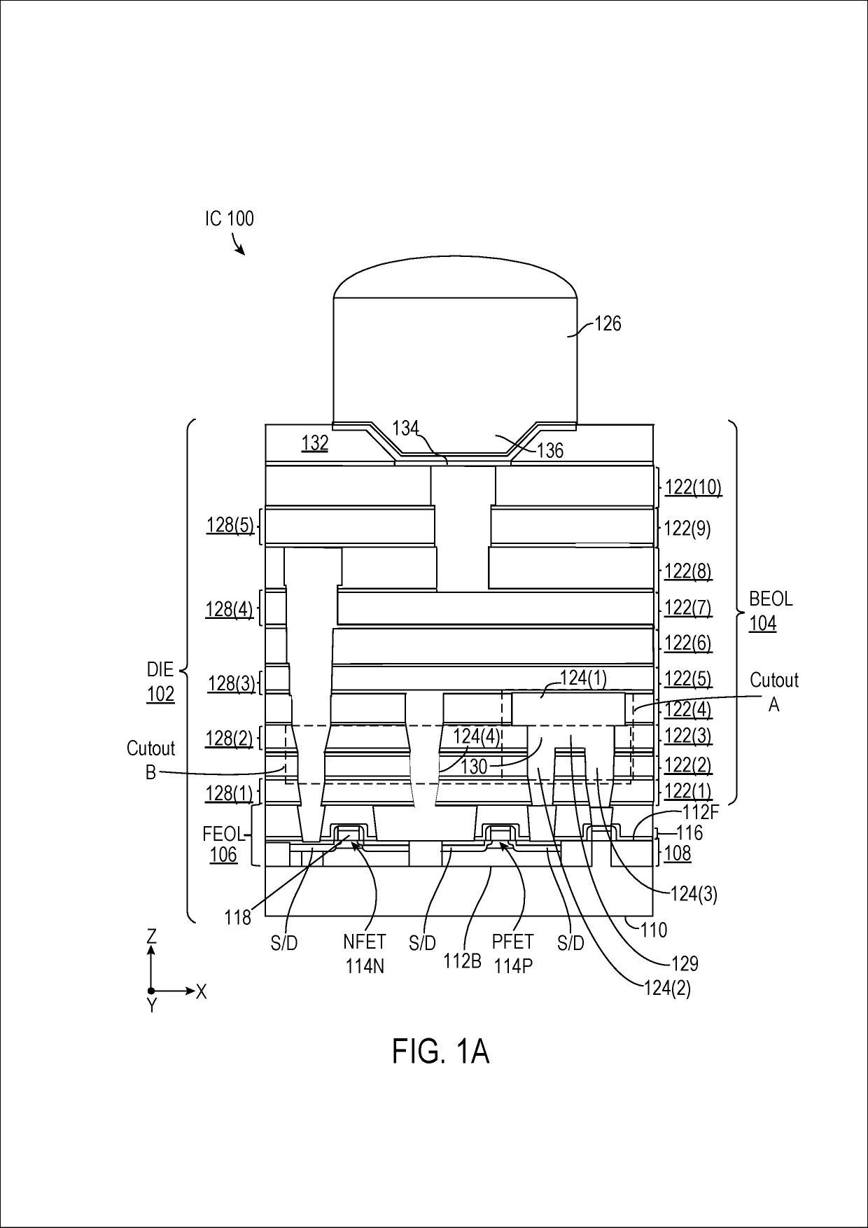

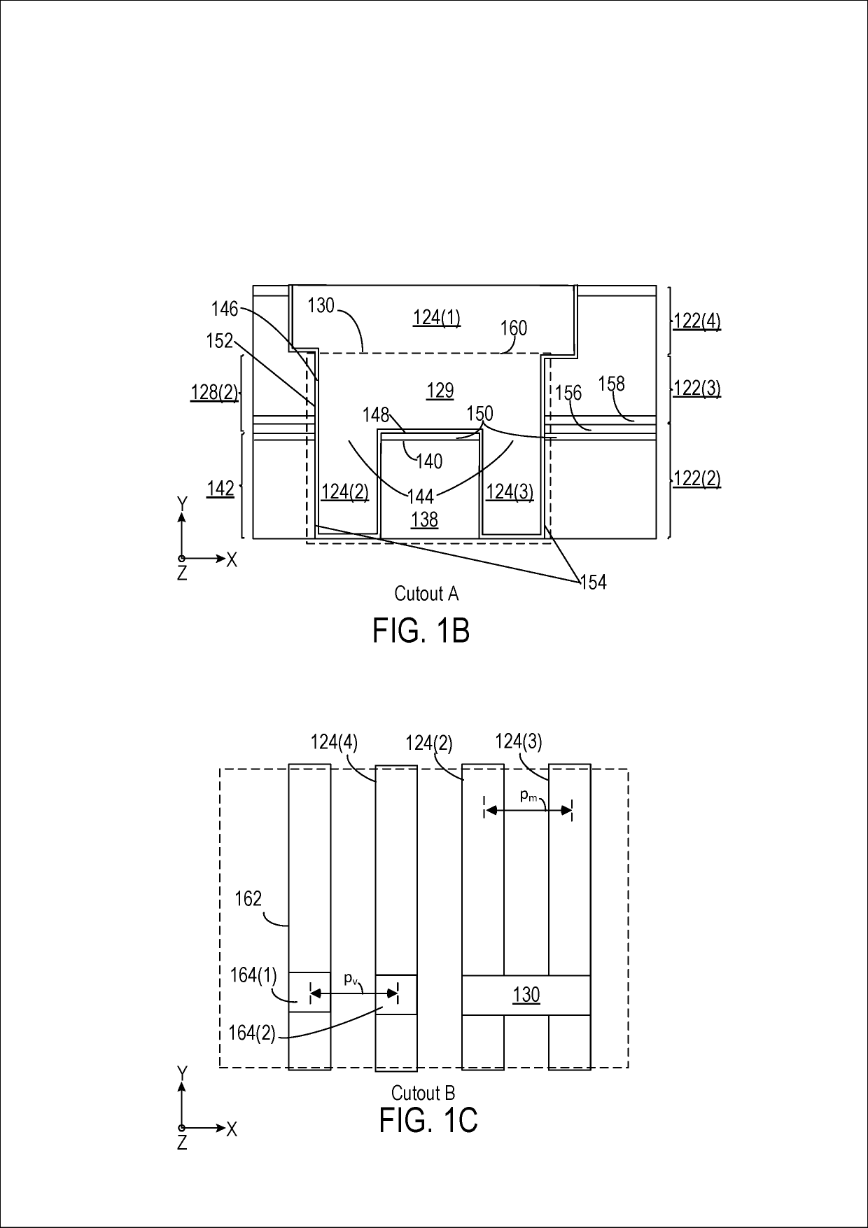

In this regard, FIG. 1A is a side view of an integrated circuit (IC) 100 that includes a portion of a die 102, the die 102 including an exemplary conductive bridge comprising a metal via coupling two adjacent metal interconnects in a single metallization layer to address tiger tooth defects. The die 102 includes a back end of line (BEOL) interconnect structure 104 formed by a BEOL process and disposed on a front-end-of-line (FEOL) structure 106. The FEOL structure 106 includes an active, semiconductor layer 108 that is formed on a substrate 110. The semiconductor layer 108 extends in a first, horizontal direction, which is the X-axis and Y-axis directions as shown in FIG. 1A. The semiconductor layer 108 has a first, front side 112F and a second, back side 112B opposite the first, front side 112F in a second, vertical direction (Z-axis direction). P-type field-effect transistors (FETs) (PFETs) and N-type FETs (NFETs) 114P, 114N are formed in the semiconductor layer 108. The FEOL structure 106 includes a contact layer 116 including a metal contact 118. The BEOL interconnect structure 104, as a front side interconnect structure 104, is disposed adjacent to the front side 112F of the semiconductor layer 108 in the second, vertical direction (Z-axis direction). The BEOL interconnect structure 104 facilitates signal routing in the die 102 on the front side 112F of the semiconductor layer 108. In this regard, the BEOL interconnect structure 104 includes a plurality of front side, metallization layers 122(1)-122(10) that each include one or more metal interconnects, such as metal interconnects 124(1)-124(4) that can provide direct or indirect interconnections between the FETs 114P, 114N and die interconnects 126 (e.g., a solder bump) adjacent to an upper metallization layer 122(10) of the BEOL interconnect structure 104. The metal interconnects 124(1)-124(4) extend in the first, horizontal direction(s) (X- and/or Y-axis directions). The BEOL interconnect structure 104 also includes via layers 128(1)-128(5) disposed through the front side, metallization layers 122(1)-122(10) to provide interconnects between metal interconnects in adjacent, vertical metallization layers. For example, via layer 128(2) includes a metal via 129 which provides interconnection between adjacent metal interconnects 124(2)-124(3) in the same metallization layer 122(2) and, in the vertical direction, metallization layer 122(4). An exemplary conductive bridge 130 comprises the metal via 129 coupled to two adjacent metal interconnects 124(2), 124(3) in a single metallization layer 122(2) to address tiger tooth defects. A first passivation layer 132 extends in the first, horizontal direction adjacent to the outer metallization layer 122(10). A metal pad 134 is disposed between the passivation layer 132 and the outer metallization layer 122(10) to mechanically support the die interconnect 126. The die interconnect 126 couples to the metal pad 134 through a via 136. The metal pad 134 couples to metal interconnect 124(3) through via layer 128(5).

FIG. 1B is close-up view of the exemplary conductive bridge 130 in FIG. 1A along cutout A. The metallization layer 122(2) includes a first dielectric layer 138 extending in a first, horizontal direction (X-, Y-axes direction). The first dielectric layer 138 has a first top surface 140. The metallization layer 122(2) also includes a metal layer 142 extending in the first, horizontal direction and formed in the first dielectric layer 138. The metal layer 142 includes a plurality of adjacent metal interconnects, such as adjacent metal interconnects 124(2), 124(3), which have a common top surface 144. The conductive bridge 130 includes a barrier/liner 146. The barrier/liner 146 prevents diffusion of metal in metal interconnects, such as the metal interconnects 124(2), 124(3) into adjacent metallization layers such as the metallization layer 122(2). Additionally, the barrier/liner 146 also acts as a seed layer during fabrication of the metal interconnects 124(2), 124(3) and the metal via 129.

The conductive bridge 130 includes the metal via 129 which has a bottom surface 148. The metal via 129 is coupled to the top surface 144 of the plurality of adjacent metal interconnects 124(2), 124(3) and extends over the first top surface 140 of the first dielectric layer 138 between the plurality of adjacent metal interconnects 124(2), 124(3). The plurality of adjacent metal interconnects 124(2), 124(3) may include two metal interconnects 124(2), 124(3). The conductive bridge 130 also includes a portion of the plurality of adjacent metal interconnects 124(2), 124(3) coupled to the bottom surface 148 of the metal via 129. The conductive bridge 130 also includes a dielectric protection layer 150 between the bottom surface 148 of the metal via 129 and the first top surface 140 of the first dielectric layer 138 and co-extensive with the bottom surface 148 of the metal via 129 between the plurality of adjacent metal interconnects 124(2), 124(3).

The dielectric protection layer 150 protects the underlying dielectric layer 138 during fabrication of the metal via 129 to prevent over etching the via prior to depositing metal. The dielectric protection layer 150 may comprise one of the following chemical compounds having any K-value including, but not limited to, silicon oxycarbide (SiOC), silicon nitride (SiN), and silicon carbon nitride (SiCN) as long as the K value is different from the K-value of dielectric layer 138.

The conductive bridge 130 includes an outer sidewall 152 extending in a second, vertical direction (Z-axis direction) and defining a periphery 154 of the conductive bridge 130. The dielectric protection layer 150 further extends in the horizontal direction on top of the first dielectric layer 138 perpendicular to the outer sidewall 152 and outside the periphery 154 of the conductive bridge 130. The semiconductor die 102 further includes a high-K dielectric layer 156 (i.e. K >= 3) extending in the horizontal direction, perpendicular to the outer sidewall 152, and on top of the dielectric protection layer 150 outside the periphery 154 of the conductive bridge. The high-K dielectric layer 156 may comprise one of the following chemical compounds having a K value greater than 3 including, but not limited to, aluminum nitride (AIN) and aluminum oxide (Al₂O₃).

The semiconductor die 102 further includes a low-K dielectric layer 158 (i.e. K < 3) extending in the horizontal direction, perpendicular to the outer sidewall 152, and on top of the high-K dielectric layer 156 outside the periphery 154 of the conductive bridge 130.

The conductive bridge 130 has a top surface 160. The semiconductor die 102 further includes a second metallization layer, such as metallization layer 122(4). The second metallization layer includes a metal interconnect, such as metal interconnect 124(1). The metal interconnect 124(1) extends in the horizontal direction on top of the top surface 160 of the conductive bridge 130.

FIG. 1C is a top-down perspective view of cutout B of the exemplary conductive bridge 130 in FIG. 1A. In this perspective, cutout B further includes a metal interconnect 162 and metal vias 164(1), 164(2) coupled to metal interconnects 162, 124(4), respectively. The metal interconnects 124(2), 124(3), 124(4), and 162 have a pitch, pₘ, measured between the center point of the respective metal interconnects. The metal vias 164(1), 164(2) have a pitch, pᵥ, measured between the center point of the respective metal vias.

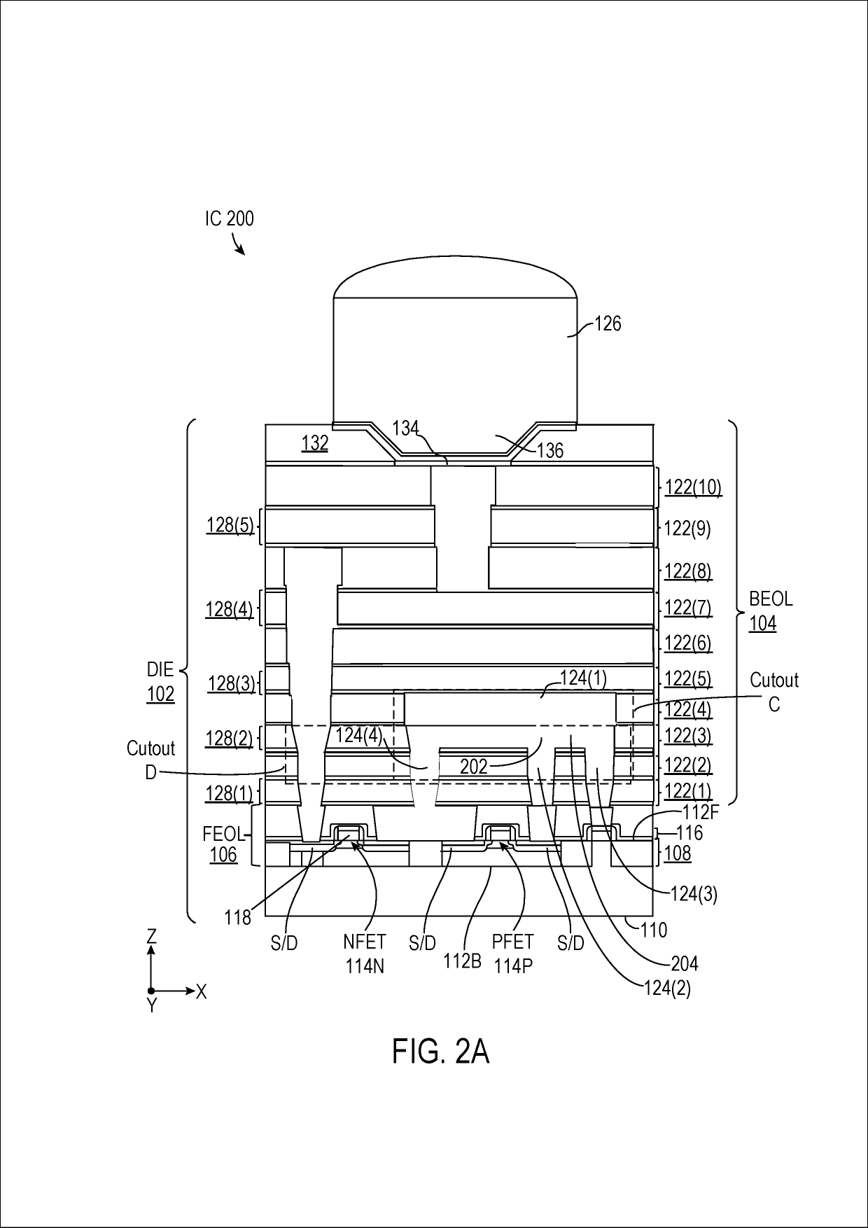

FIG. 2A is a side view of an integrated circuit (IC) 200 that includes a portion of a die 102, the die 102 including another exemplary conductive bridge 202 comprising a metal via 204 coupling three adjacent metal interconnects 124(2), 124(3), and 123(4) in a single metallization layer 122(2) to address tiger tooth defects. Common elements between the IC 200 in FIGS. 2A-2C and the IC 100 in FIGS. 1A-1C are shown with common element numbers.

FIG. 2B is a close-up view of the exemplary conductive bridge 202 in FIG. 2A along cutout C. The metal layer 142 includes a plurality of adjacent metal interconnects, such as adjacent metal interconnects 124(2), 124(3), 124(4) which have a common top surface 144. The metal via 204 is coupled to the top surface 144 of the plurality of adjacent metal interconnects 124(2), 124(3), 124(4) and extends over the first top surface 140 of the first dielectric layer 138 between the plurality of adjacent metal interconnects 124(2), 124(3), 124(4). The plurality of adjacent metal interconnects 124(2), 124(3), 124(4) may include three metal interconnects 124(2), 124(3), 124(4). The conductive bridge 202 also includes a portion of the plurality of adjacent metal interconnects 124(2), 124(3), 124(4) coupled to the bottom surface 148 of the metal via 204. Although the conductive bridge 202 couples three adjacent metal interconnects, other conductive bridges coupling more than three adjacent metal interconnects may be fabricated utilizing the same structure described in FIGS. 1A-1C and 2A-2C.

FIG. 2C is a top-down perspective view of cutout D of the exemplary conductive bridge 202 in FIG. 2A.

Although the conductive bridges 130, 202 are illustrated and discussed in connection with coupling metal interconnects in metallization layer 122(2), other conductive bridges described in FIGS. 1A-1C and 2A-2C may be fabricated in any of the metallization layers in a BEOL structure 104.

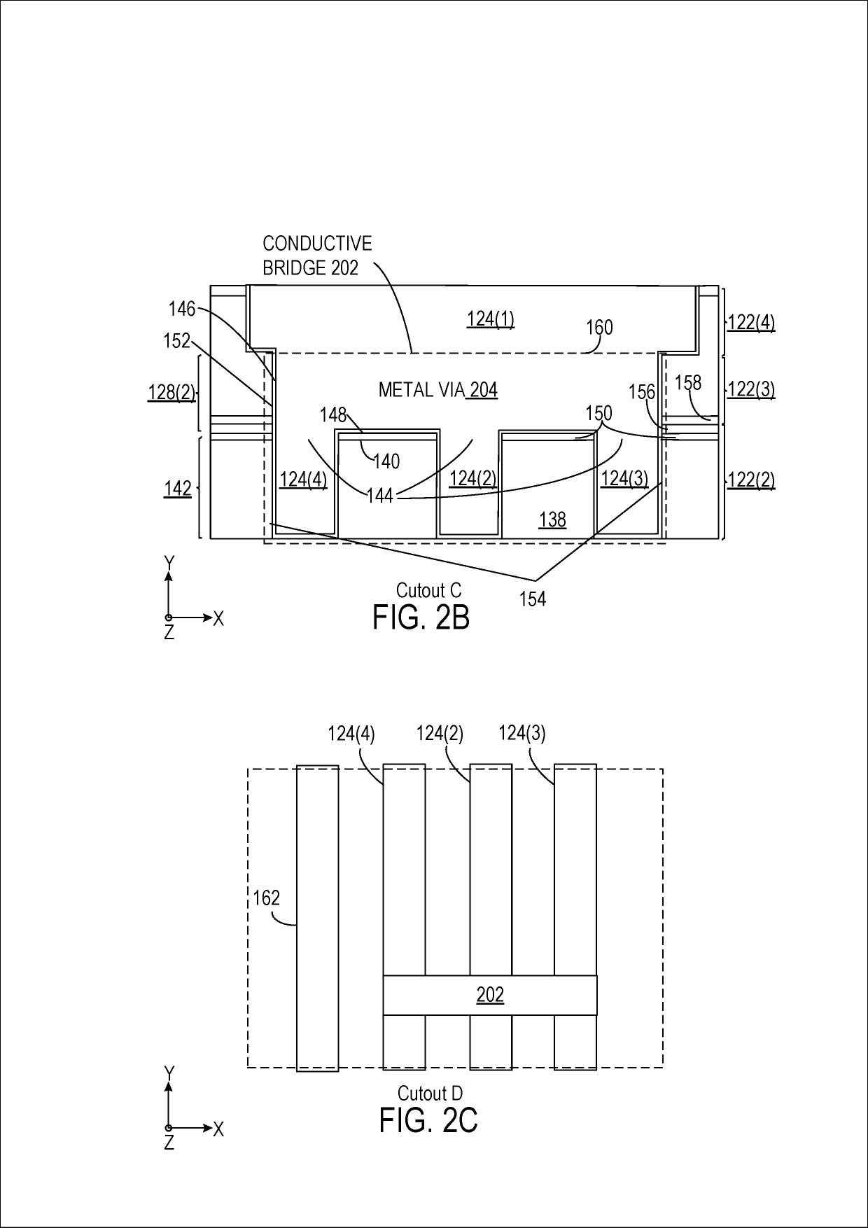

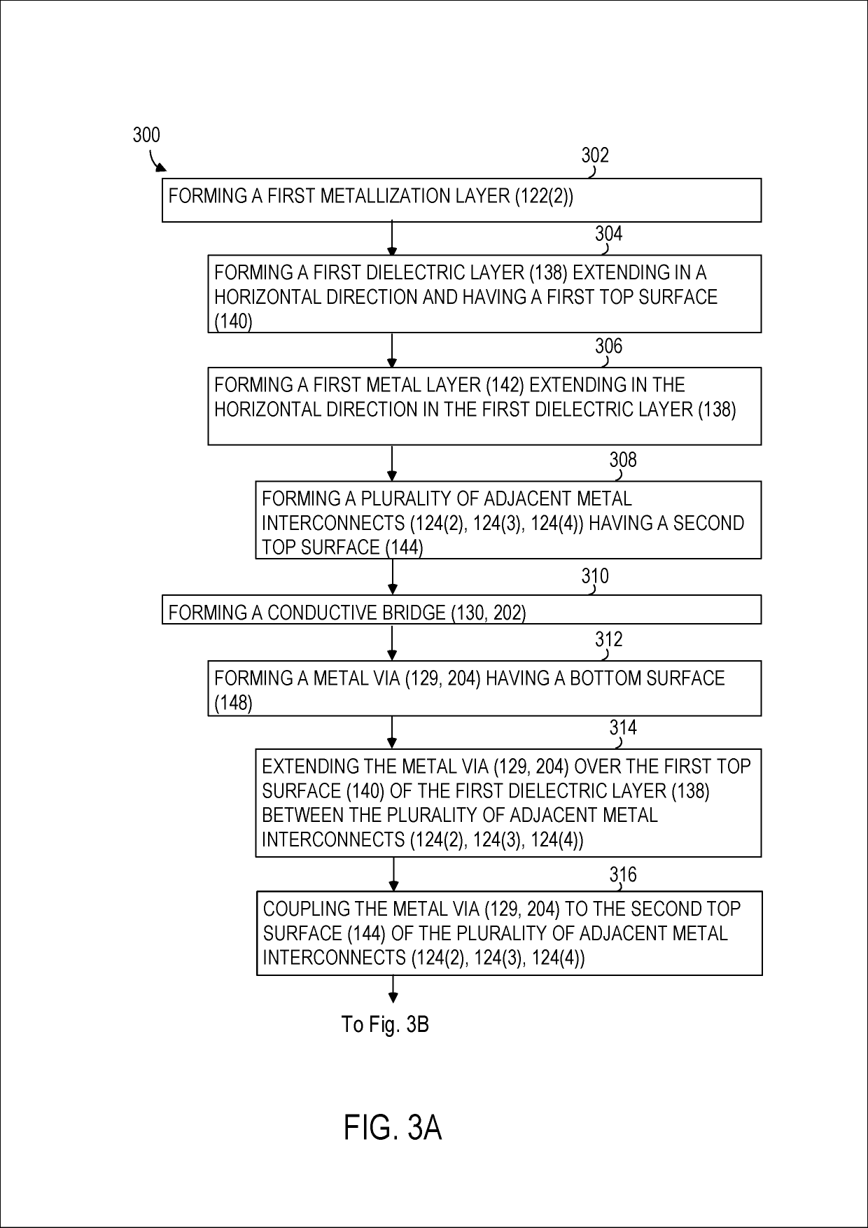

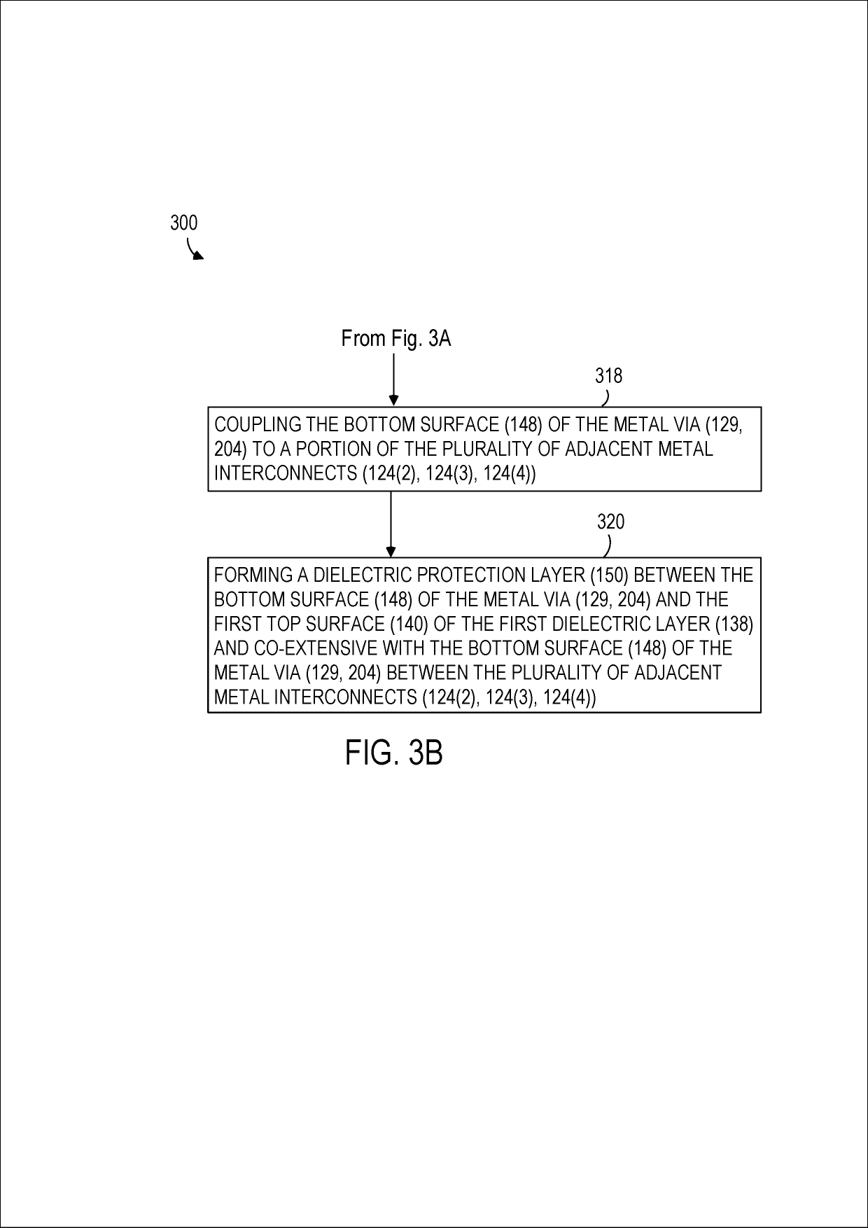

An IC including a die employing a conductive bridge comprising a metal via coupling two adjacent metal interconnects in a single metallization layer to address tiger tooth defects, including, but not limited to, the conductive bridges 130, 202 in FIGS. 1A-1C, 2A-2C, respectively can be fabricated by different fabrication processes. FIGS. 3A-3B is a flowchart illustrating an exemplary fabrication process 300 of fabricating a semiconductor die including a conductive bridge described in FIGS. 1A-1C and 2A-2C, in a BEOL process wherein the conductive bridge comprises a metal via coupling two adjacent metal interconnects in a single layer to address tiger tooth defects, including, but not limited to, the conductive bridges in FIGS. 1A-1C and 2A-2C.

In this regard, a first exemplary step in the fabrication process 300 of FIGS. 3A-3B can include forming a first metallization layer 122(2) (block 302 in FIG. 3A). Forming the first metallization layer 122(2) in block 302 may include forming a first dielectric layer 138 extending in a horizontal direction and having a first top surface 140 (block 304 in FIG. 3A). The next step in forming the first metallization layer 122(2) in block 302 can include forming a first metal layer 142 extending in the horizontal direction in the first dielectric layer 138 (block 306 in FIG. 3A). Forming the first metal layer 142 may include forming a plurality of adjacent metal interconnects 124(2), 124(3), 124(4) having a second top surface 144 (block 308 in FIG. 3A).

The next step in the fabrication process 300 can include forming a conductive bridge 130, 202 (block 310 in FIG. 3A). Forming the conductive bridge 130, 202 in block 310 can include forming a metal via 129, 204 having a bottom surface 148 (block 312 in FIG. 3A). Forming the metal via in block 312 can include extending the metal via 129, 204 over the first top surface 140 of the first dielectric layer 138 between the plurality of adjacent metal interconnects 124(2), 124(3), 124(4) (block 314 in FIG. 3A). The next step in the forming the metal via in block 312 can include coupling the metal via 129, 204 to the second top surface 144 of the plurality of adjacent metal interconnects 124(2), 124(3), 124(4) (block 316 in FIG. 3A).

The next step in forming the conductive bridge 130, 202 in block 310 can include coupling the bottom surface 148 of the metal via 129, 204 to a portion of the plurality of adjacent metal interconnects 124(2), 124(3), 124(4) (block 318 in FIG. 3B). The next step in forming the conductive bridge 130, 202 in block 310 can include forming a dielectric protection layer 150 between the bottom surface 148 of the metal via 129, 204 and the first top surface 140 of the first dielectric layer 138 and co-extensive with the bottom surface 148 of the metal via 129, 204 between the plurality of adjacent metal interconnects 124(2), 124(3), 124(4) (block 320 in FIG. 3B).

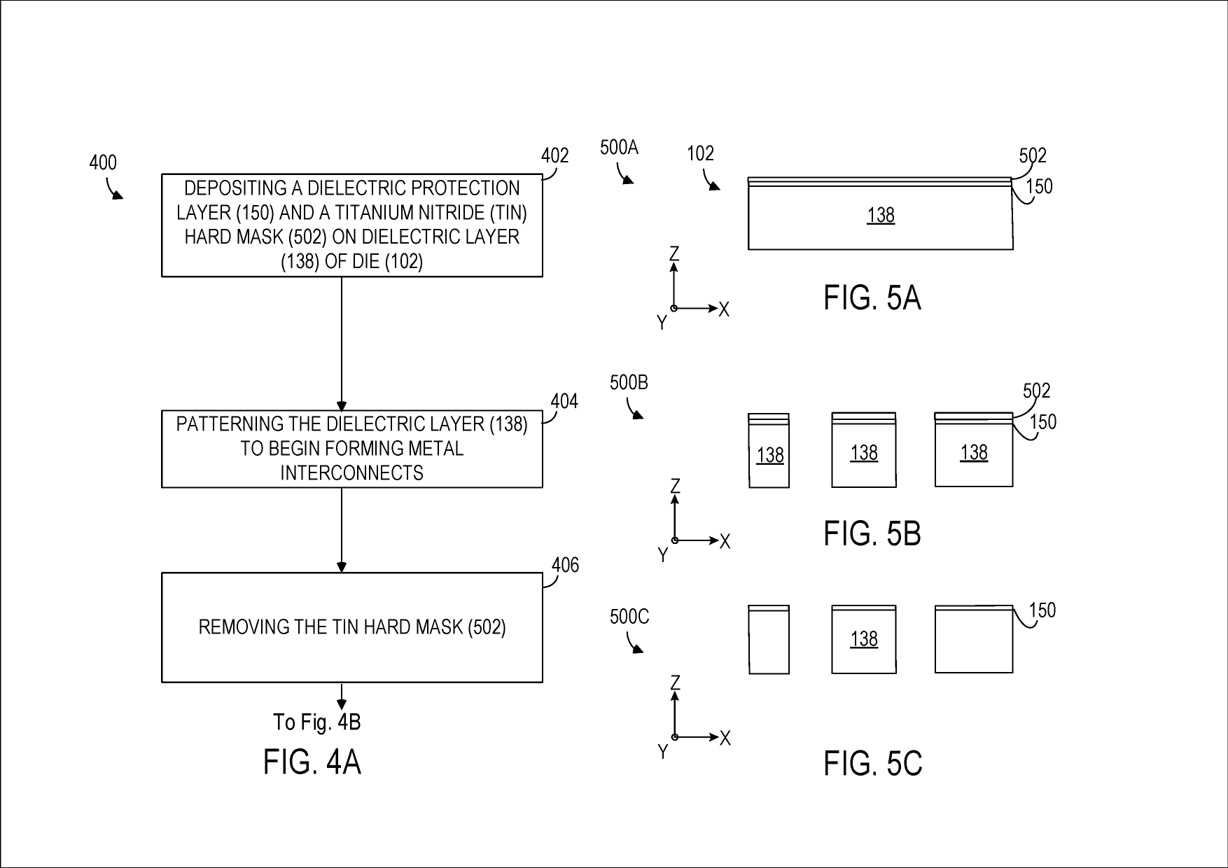

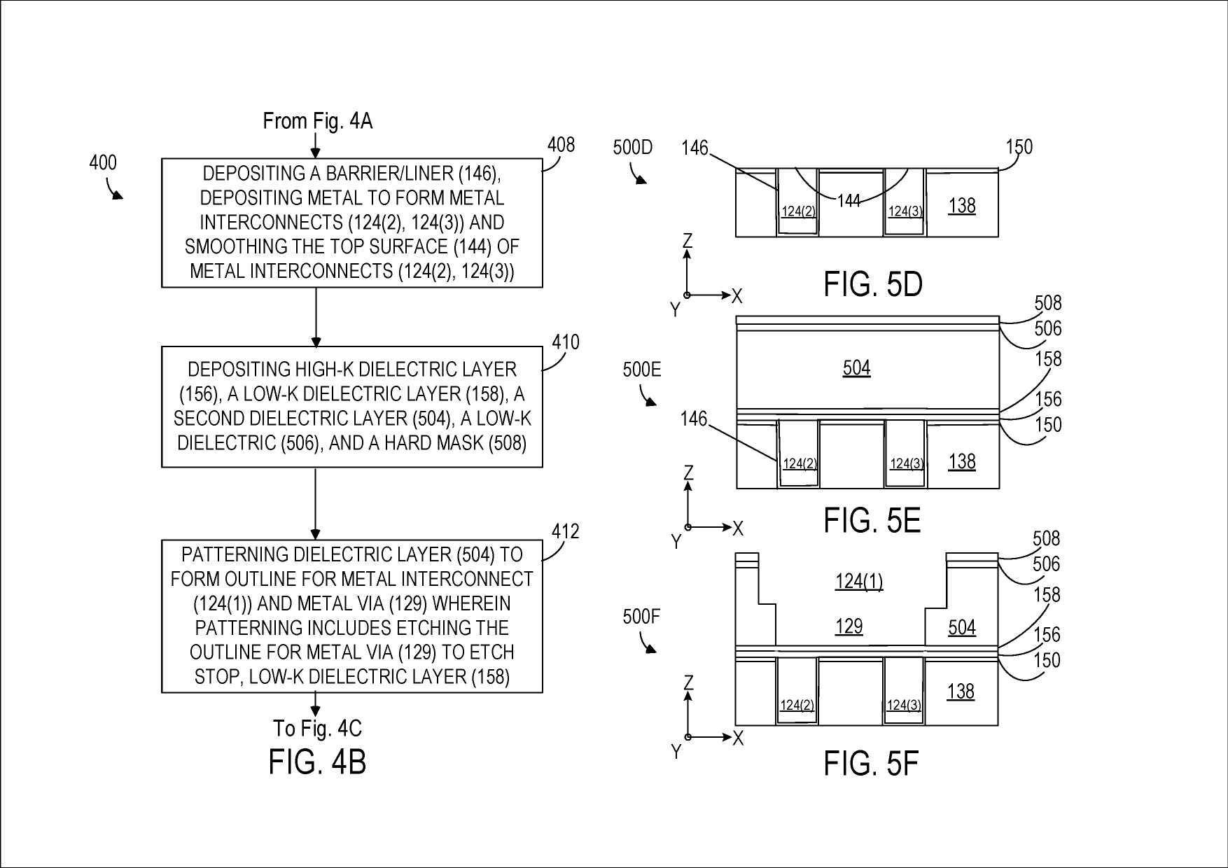

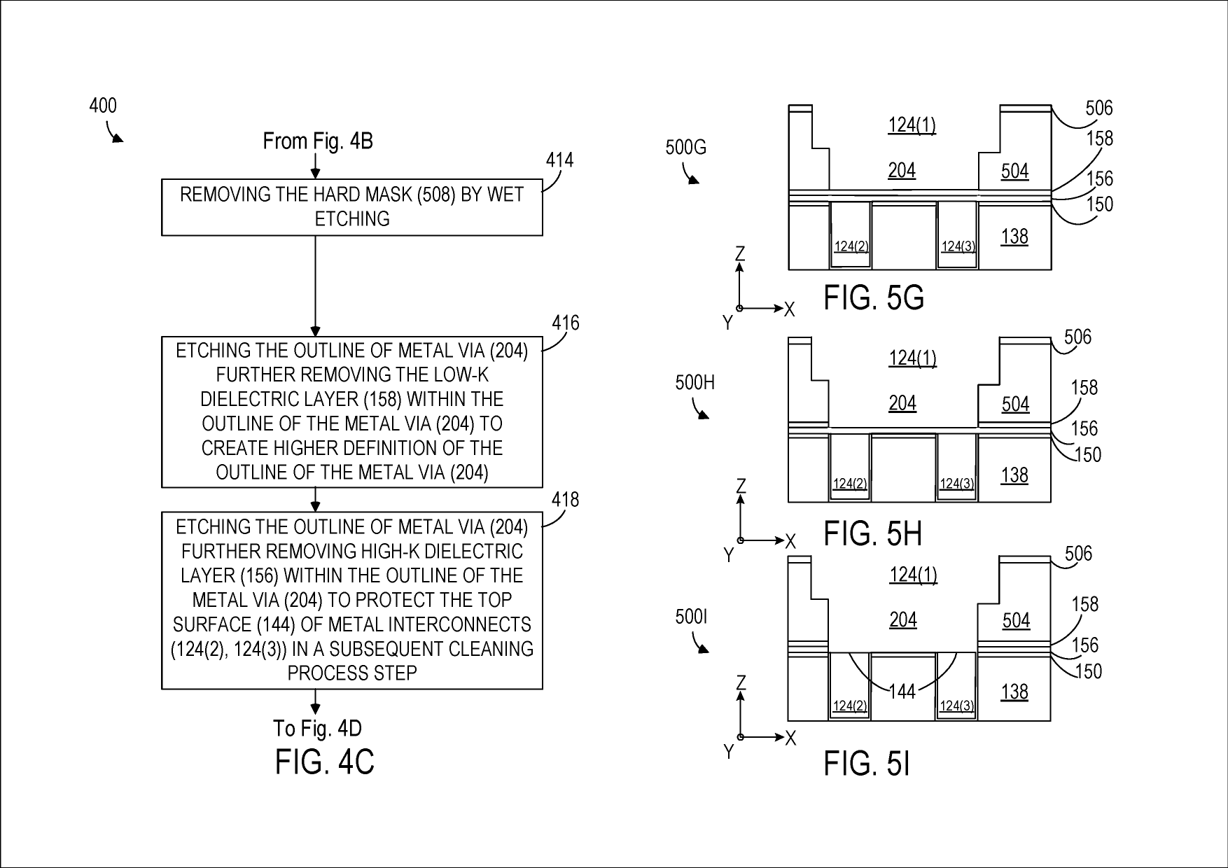

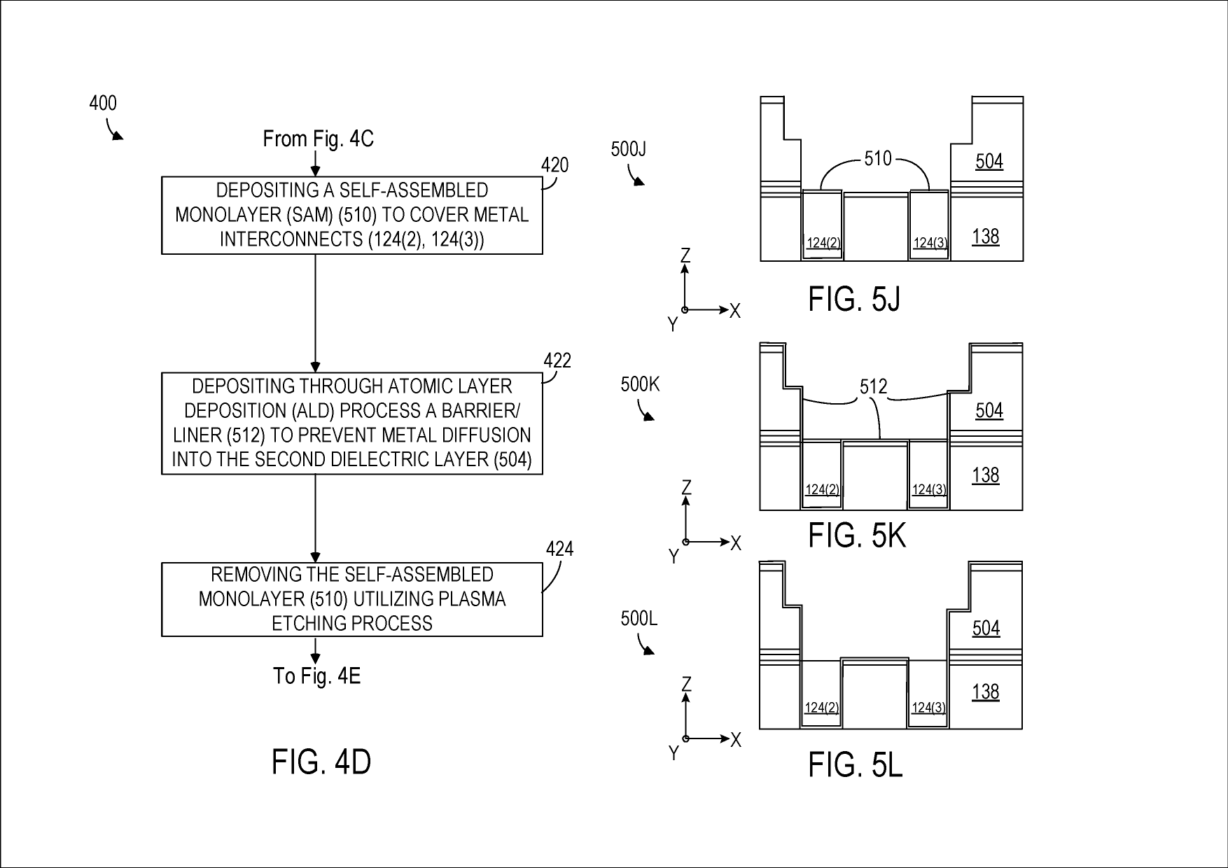

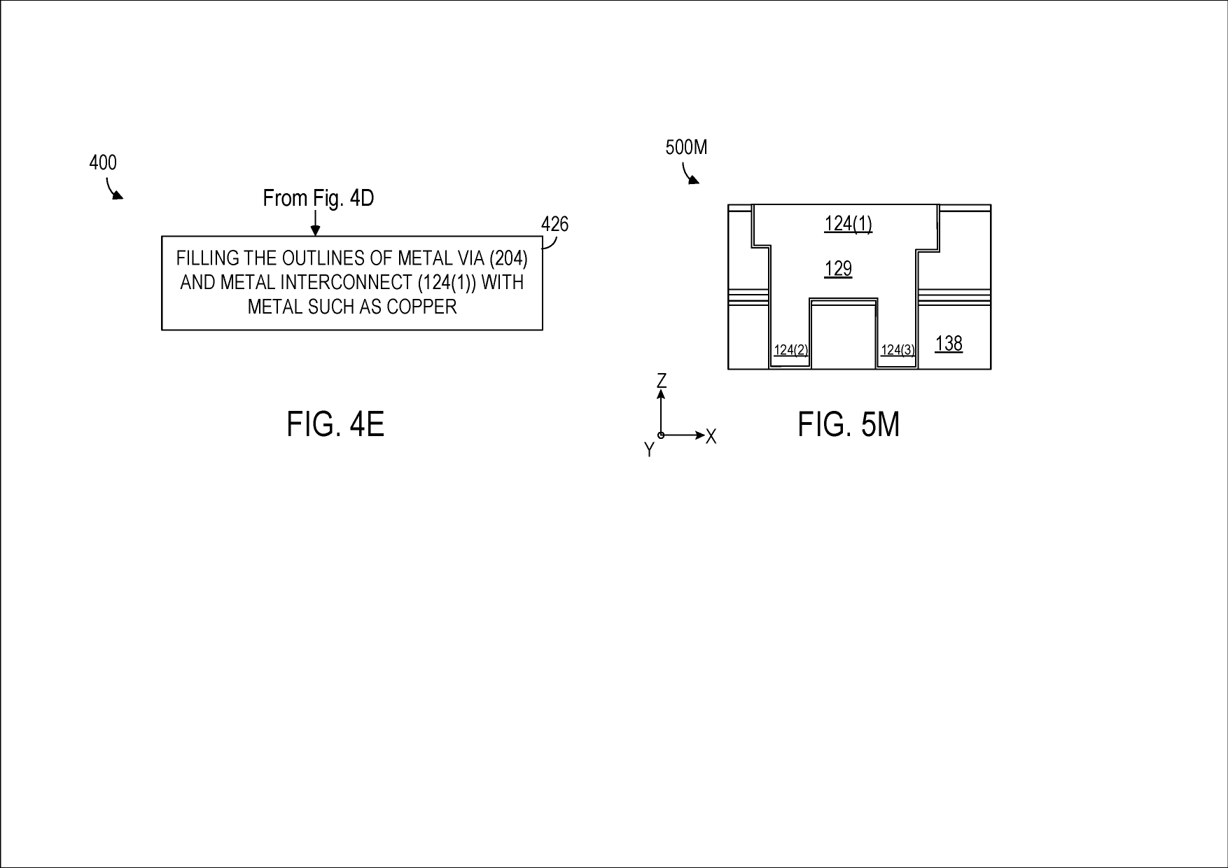

Other fabrication processes can also be employed to fabricate an IC including a die employing a conductive bridge comprising a metal via coupling two adjacent metal interconnects in a single metallization layer to address tiger tooth defects, including, but not limited to, the conductive bridges 130, 202 in FIGS. 1A-1C, 2A-2C, respectively. In this regard FIGS. 4A-4E is a flowchart illustrating another exemplary fabrication process 400 of fabricating a conductive bridge such as the conductive bridges described in FIGS. 1A-1C and 2A-2C, in a BEOL process wherein the conductive bridge comprises a metal via coupling two adjacent metal interconnects in a single layer to address tiger tooth defects, including, but not limited to, the conductive bridges in FIGS. 1A-1C and 2A-2C. FIGS. 5A-5M are exemplary fabrication stages during fabrication of the IC package according to the fabrication process in FIGS. 4A-4E. The fabrication process 400 as shown in the fabrication stages 500A-500M in FIGS. 5A-5M are in reference to the IC 100 in FIGS. 1A-1C, and thus will be discussed with reference to the IC 100, and, in particular, the conductive bridge 130 in FIGS. 1A-1C. As such, the layers below metallization layer 122(2) and above metallization layer 122(4) are not discussed.

In this regard, as shown in fabrication stage 500A in FIG. 5A, an exemplary step in the fabrication process 400 is depositing a dielectric protection layer 150 and a titanium nitride (TiN) hard mask 502 on the dielectric layer 138 of the die 102 (block 402 in FIG. 4A). The dielectric layer 138 contains a higher concentration of carbon (C) than the dielectric protection layer 150. For example, the dielectric layer 138 may comprise carbon doped oxide (SiCOH) while the dielectric protection layer 150 may comprise silicon oxycarbide (SiOC). As shown at fabrication stage 500B in FIG. 5B, a next step in the fabrication process 400 can include patterning the dielectric layer 138 to begin forming metal interconnects (block 404 in FIG. 4A). As shown at fabrication stage 500C in FIG. 5C, a next step in the fabrication process 400 can include removing the TiN hard mask 502 through, for example, a wet etching process (block 406 in FIG. 4A).

As shown at fabrication stage 500D in FIG. 5D, a next step in the fabrication process 400 can include depositing a barrier/liner 146, depositing metal to form metal interconnects 124(2), 124(3) and smoothing the top surface 144 of the metal interconnects 124(2), 124(3) through a chemical mechanical planarization (CMP) process (block 408 in FIG. 4B). As shown at fabrication stage 500E in FIG. 5E, a next step in the fabrication process 400 can include depositing a high-K dielectric layer 156, a low-K dielectric layer 158, a second dielectric layer 504, a dielectric protection layer 506, and a hard mask 508 (block 410 in FIG. 4B). The high-K dielectric layer 156 has an etch rate that is roughly five times more than the etch rate of the dielectric protection layer 150. In other words, the etch selectivity of high-K dielectric layer 156 to the dielectric protection layer 150 is equal to or greater than 5:1. This etch selectivity further address alleviating the tiger tooth defects during fabrication.

As shown at fabrication stage 500F in FIG. 5F, a next step in the fabrication process 400 can include patterning the second dielectric layer 504 to form an outline for the metal interconnect 124(1) and the metal via 129 wherein patterning includes etching the outline for the metal via 129 to the etch stop, low-K dielectric layer 158 (block 412 in FIG. 4B).

As shown at fabrication stage 500G in FIG. 5G, a next step in the fabrication process 400 can include removing the hard mask 508 by wet etching (block 414 in FIG. 4C). As shown at fabrication stage 500H in FIG. 5H, a next step in the fabrication process 400 can include etching the outline of the metal via 129 further removing the low-K dielectric layer 158 within the outline of the metal via 129 to create higher definition of the outline of the metal via 129 (block 416 in FIG. 4C). As shown at fabrication stage 500I in FIG. 5I, a next step in the fabrication process 400 can include etching the outline of the metal via 129 further removing the high-K dielectric layer 156 within the outline of the metal via 129 to protect the top surface 144 of the metal interconnects 124(2), 124(3) in a subsequent cleaning process step (block 418 in FIG. 4C).

As shown at fabrication stage 500J in FIG. 5J, a next step in the fabrication process 400 can include depositing a self-assembled monolayer (SAM) 510 to cover the metal interconnects 124(2), 124(3) (block 420 in FIG. 4D). As shown at fabrication stage 500K in FIG. 5K, a next step in the fabrication process 400 can include depositing through an atomic layer deposition (ALD) process a barrier/liner 512 to prevent metal diffusion into the second dielectric layer 504. The barrier/liner 512 may be composed of tantalum nitride (TaN) (block 422 in FIG. 4D). As shown at fabrication stage 500L in FIG. 5L, a next step in the fabrication process 400 can include removing the SAM 510 utilizing a plasma etching process (block 424 in FIG. 4D). As shown at fabrication stage 500M in FIG. 5M, a next step in the fabrication process 400 can include filling the outlines of the metal via 129 and the metal interconnect 124(1) with metal such as copper (block 426 in FIG. 4E).

Electronic devices that include a semiconductor die that includes a conductive bridge such as the conductive bridges described in FIGS. 1A-1C and 2A-2C, in a BEOL process wherein the conductive bridge comprises a metal via coupling two adjacent metal interconnects in a single layer to address tiger tooth defects, including, but not limited to, the conductive bridges in FIGS. 1A-1C and 2A-2C, and according to any aspects disclosed herein, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, laptop computer, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, and a multicopter.

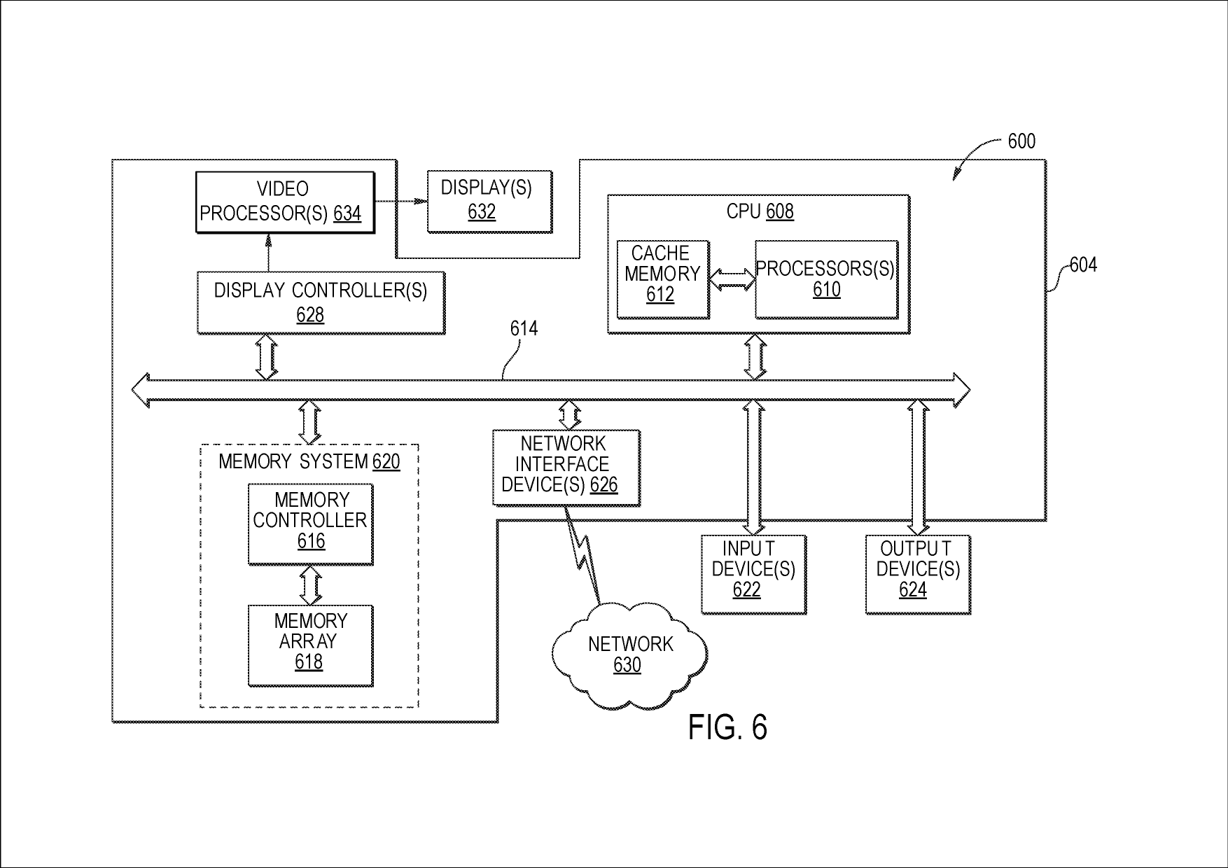

In this regard, FIG. 6 is a block diagram of an exemplary processor-based system 600 that can include components deployed in a die, wherein the die includes an exemplary conductive bridge comprising a metal via coupling two adjacent metal interconnects in a single metallization layer to address tiger tooth defects, including, but not limited to, the conductive bridges in FIGS. 1A-1C and 2A-2C and according to the exemplary fabrication processes in FIGS. 3 and 4A-4E, and according to any exemplary aspects disclosed herein. In this example, the processor-based system 600 may be formed as an IC 604 such as the ICs 100, 200 in FIGS. 1A and 2A, respectively. The processor-based system 600 includes a central processing unit (CPU) 608 that includes one or more processors 610, which may also be referred to as CPU cores or processor cores. The CPU 608 may have cache memory 612 coupled to the processor(s) 610 for rapid access to temporarily stored data. The CPU 608 is coupled to a system bus 614 and can intercouple master and slave devices included in the processor-based system 600. As is well known, the CPU 608 communicates with these other devices by exchanging address, control, and data information over the system bus 614. For example, the CPU 608 can communicate bus transaction requests to a memory controller 616, as an example of a slave device. Although not illustrated in FIG. 6, multiple system buses 614 could be provided, wherein each system bus 614 constitutes a different fabric.

Other master and slave devices can be connected to the system bus 614. As illustrated in FIG. 6, these devices can include a memory system 620 that includes the memory controller 616 and a memory array(s) 618, one or more input devices 622, one or more output devices 624, one or more network interface devices 626, and one or more display controllers 628, as examples. Each of the memory system 620, the one or more input devices 622, the one or more output devices 624, the one or more network interface devices 626, and the one or more display controllers 628 can be provided in the same or different electronic devices. The input device(s) 622 can include any type of input device, including, but not limited to, input keys, switches, voice processors, etc. The output device(s) 624 can include any type of output device, including, but not limited to, audio, video, other visual indicators, etc. The network interface device(s) 626 can be any device configured to allow exchange of data to and from a network 630. The network 630 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 626 can be configured to support any type of communications protocol desired.

The CPU 608 may also be configured to access the display controller(s) 628 over the system bus 614 to control information sent to one or more displays 632. The display controller(s) 628 sends information to the display(s) 632 to be displayed via one or more video processor(s) 634, which process the information to be displayed into a format suitable for the display(s) 632. The display controller(s) 628 and video processor(s) 634 can be included as ICs in the same or different electronic devices, and in the same or different electronic devices containing the CPU 608, as an example. The display(s) 632 can include any type of display, including, but not limited to, a cathode ray tube (CRT), a liquid crystal display (LCD), a plasma display, a light emitting diode (LED) display, etc.

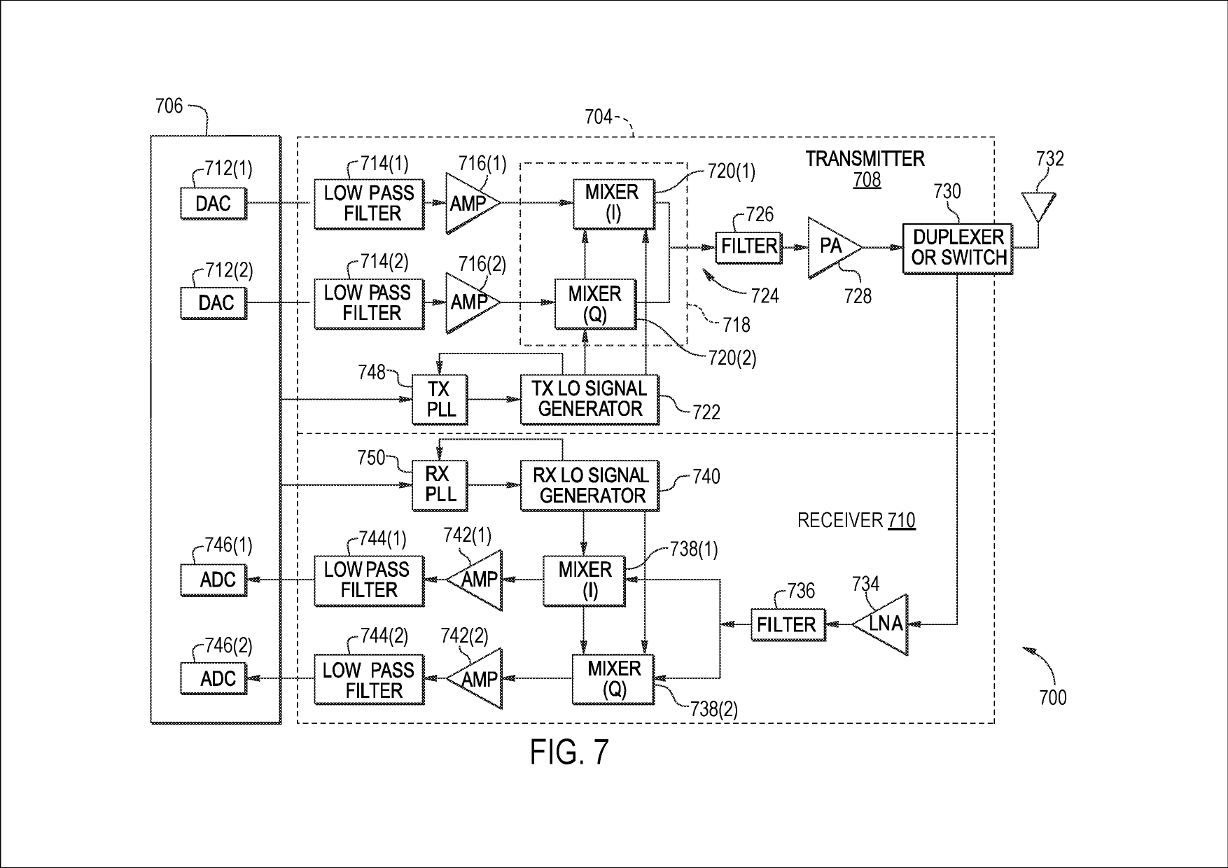

FIG. 7 is a block diagram of an exemplary wireless communications device 700 that includes radio-frequency (RF) components formed from one or more dies, wherein any of the dies includes an exemplary conductive bridge comprising a metal via coupling two adjacent metal interconnects in a single metallization layer to address tiger tooth defects, including, but not limited to, the conductive bridges in FIGS. 1A-1C and 2A-2C and according to the exemplary fabrication processes in FIGS. 3 and 4A-4E, and according to any exemplary aspects disclosed herein. The wireless communications device 700 may include or be provided in any of the above-referenced devices, as examples. As shown in FIG. 7, the wireless communications device 700 includes a transceiver 704 and a data processor 706. The data processor 706 may include a memory to store data and program codes. The transceiver 704 includes a transmitter 708 and a receiver 710 that support bi-directional communications. In general, the wireless communications device 700 may include any number of transmitters 708 and/or receivers 710 for any number of communication systems and frequency bands. All or a portion of the transceiver 704 may be implemented on one or more analog ICs, RF ICs (RFICs), mixed-signal ICs, etc.

The transmitter 708 or the receiver 710 may be implemented with a super-heterodyne architecture or a direct-conversion architecture. In the super-heterodyne architecture, a signal is frequency-converted between RF and baseband in multiple stages, for example, from RF to an intermediate frequency (IF) in one stage, and then from IF to baseband in another stage for the receiver 710. In the direct-conversion architecture, a signal is frequency-converted between RF and baseband in one stage. The super-heterodyne and direct-conversion architectures may use different circuit blocks and/or have different requirements. In the wireless communications device 700 in FIG. 7, the transmitter 708 and the receiver 710 are implemented with the direct-conversion architecture.

In the transmit path, the data processor 706 processes data to be transmitted and provides I and Q analog output signals to the transmitter 708. In the exemplary wireless communications device 700, the data processor 706 includes digital-to-analog converters (DACs) 712(1), 712(2) for converting digital signals generated by the data processor 706 into the I and Q analog output signals (e.g., I and Q output currents) for further processing.

Within the transmitter 708, lowpass filters 714(1), 714(2) filter the I and Q analog output signals, respectively, to remove undesired signals caused by the prior digital-to-analog conversion. Amplifiers (AMPs) 716(1), 716(2) amplify the signals from the lowpass filters 714(1), 714(2), respectively, and provide I and Q baseband signals. An upconverter 718 upconverts the I and Q baseband signals with I and Q transmit (TX) local oscillator (LO) signals through mixers 720(1), 720(2) from a TX LO signal generator 722 to provide an upconverted signal 724. A filter 726 filters the upconverted signal 724 to remove undesired signals caused by the frequency up-conversion as well as noise in a receive frequency band. A power amplifier (PA) 728 amplifies the upconverted signal 724 from the filter 726 to obtain the desired output power level and provides a transmit RF signal. The transmit RF signal is routed through a duplexer or switch 730 and transmitted via an antenna 732.

In the receive path, the antenna 732 receives signals transmitted by base stations and provides a received RF signal, which is routed through the duplexer or switch 730 and provided to a low noise amplifier (LNA) 734. The duplexer or switch 730 is designed to operate with a specific receive (RX)-to-TX duplexer frequency separation, such that RX signals are isolated from TX signals. The received RF signal is amplified by the LNA 734 and filtered by a filter 736 to obtain a desired RF input signal. Down-conversion mixers 738(1), 738(2) mix the output of the filter 736 with I and Q RX LO signals (i.e., LO_I and LO_Q) from an RX LO signal generator 740 to generate I and Q baseband signals. The I and Q baseband signals are amplified by AMPs 742(1), 742(2) and further filtered by lowpass filters 744(1), 744(2) to obtain I and Q analog input signals, which are provided to the data processor 706. In this example, the data processor 706 includes analog-to-digital converters (ADCs) 746(1), 746(2) for converting the analog input signals into digital signals to be further processed by the data processor 706.

In the wireless communications device 700 of FIG. 7, the TX LO signal generator 722 generates the I and Q TX LO signals used for frequency up-conversion, while the RX LO signal generator 740 generates the I and Q RX LO signals used for frequency down-conversion. Each LO signal is a periodic signal with a particular fundamental frequency. A TX phase-locked loop (PLL) circuit 748 receives timing information from the data processor 706 and generates a control signal used to adjust the frequency and/or phase of the TX LO signals from the TX LO signal generator 722. Similarly, an RX PLL circuit 750 receives timing information from the data processor 706 and generates a control signal used to adjust the frequency and/or phase of the RX LO signals from the RX LO signal generator 740.

Those of skill in the art will further appreciate that the various illustrative logical blocks, modules, circuits, and algorithms described in connection with the aspects disclosed herein may be implemented as electronic hardware, instructions stored in memory or in another computer readable medium wherein any such instructions are executed by a processor or other processing device, or combinations of both. The devices and components described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:

1. A semiconductor die, comprising:

a first metallization layer, comprising:

a first dielectric layer extending in a horizontal direction and having a first top surface; and

a first metal layer extending in the horizontal direction and formed in the first dielectric layer, the first metal layer comprising:

a plurality of adjacent metal interconnects having a second top surface; and

a conductive bridge comprising:

a metal via having a bottom surface, the metal via coupled to the second top surface of the plurality of adjacent metal interconnects and extending over the first top surface of the first dielectric layer between the plurality of adjacent metal interconnects;

a portion of the plurality of adjacent metal interconnects coupled to the bottom surface of the metal via; and

a dielectric protection layer between the bottom surface of the metal via and the first top surface of the first dielectric layer and co-extensive with the bottom surface of the metal via between the plurality of adjacent metal interconnects.

2. The semiconductor die of clause 1, wherein the dielectric protection layer is selected from a group consisting of silicon oxycarbide (SiOC), silicon nitride (SiN), and silicon carbon nitride (SiCN).

3. The semiconductor die of clause 1 or 2, wherein:

the conductive bridge comprises an outer sidewall extending in a vertical direction and defining a periphery of the conductive bridge;

the dielectric protection layer further extends in the horizontal direction on top of the first dielectric layer perpendicular to the outer sidewall and outside the periphery of the conductive bridge; and

the semiconductor die further comprises:

a high-K dielectric layer extending in the horizontal direction, perpendicular to the outer sidewall, and on top of the dielectric protection layer outside the periphery of the conductive bridge.

4. The semiconductor die of clause 3, wherein the high-K dielectric layer is selected from a group consisting of aluminum nitride (AIN) and aluminum oxide (Al₂O₃).

5. The semiconductor die of clause 3, further comprising:

a low-K dielectric layer extending in the horizontal direction, perpendicular to the outer sidewall, and on top of the high-K dielectric layer outside the periphery of the conductive bridge.

6. The semiconductor die of any of clauses 1-5,

wherein the conductive bridge has a third top surface,

the semiconductor die further comprising:

a second metallization layer, comprising:

a metal interconnect extending in the horizontal direction on top of the third top surface of the conductive bridge.

7. The semiconductor die of any of clauses 1-6, wherein the plurality of adjacent metal interconnects comprises two metal interconnects.

8. The semiconductor die of any of clauses 3-7, wherein:

the high-K dielectric layer has a first etch rate and the dielectric protection layer has a second etch rate,

a ratio between the first etch rate and the second etch rate is equal to or greater than 5:1.

9. The semiconductor die of any of clauses 1-8 integrated into a device selected from a group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics systems; and a multicopter.

10. A method of fabricating a semiconductor die, comprising:

forming a first metallization layer, comprising:

forming a first dielectric layer extending in a horizontal direction and having a first top surface; and

forming a first metal layer extending in the horizontal direction in the first dielectric layer, forming the first metal layer comprising:

forming a plurality of adjacent metal interconnects having a second top surface; and

forming a conductive bridge comprising:

forming a metal via having a bottom surface, comprising:

extending the metal via over the first top surface of the first dielectric layer between the plurality of adjacent metal interconnects; and

coupling the metal via to the second top surface of the plurality of adjacent metal interconnects;

coupling the bottom surface of the metal via to a portion of the plurality of adjacent metal interconnects; and

forming a dielectric protection layer between the bottom surface of the metal via and the first top surface of the first dielectric layer and co-extensive with the bottom surface of the metal via between the plurality of adjacent metal interconnects.

11. The method of clause 10, wherein the dielectric protection layer is selected from a group consisting of silicon oxycarbide (SiOC), silicon nitride (SiN), and silicon carbon nitride (SiCN).

12. The method of clause 10 or 11, wherein:

the conductive bridge comprises an outer sidewall extending in a vertical direction and defining a periphery of the conductive bridge;

the dielectric protection layer further extends in the horizontal direction on top of the first dielectric layer perpendicular to the outer sidewall and outside the periphery of the conductive bridge; and

the method further comprises:

forming a high-K dielectric layer extending in the horizontal direction, perpendicular to the outer sidewall, and on top of the dielectric protection layer outside the periphery of the conductive bridge.

13. The method of clause 12, wherein the high-K dielectric layer is selected from a group consisting of aluminum nitride (AIN) and aluminum oxide (Al₂O₃).

14. The method of clause 12, further comprising:

forming a low-K dielectric layer extending in the horizontal direction, perpendicular to the outer sidewall, and on top of the high-K dielectric layer outside the periphery of the conductive bridge.

15. The method of any of clauses 10-14,

wherein the conductive bridge has a third top surface,

the method further comprising:

forming a second metallization layer, comprising:

forming a metal interconnect extending in the horizontal direction on top of the third top surface of the conductive bridge.

What is claimed is:

1. A semiconductor die, comprising:
a first metallization layer, comprising:
a first dielectric layer extending in a horizontal direction and having a first top surface; and
a first metal layer extending in the horizontal direction and formed in the first dielectric layer, the first metal layer comprising:
a plurality of adjacent metal interconnects having a second top surface; and
a conductive bridge comprising:
a metal via having a bottom surface, the metal via coupled to the second top surface of the plurality of adjacent metal interconnects and extending over the first top surface of the first dielectric layer between the plurality of adjacent metal interconnects;
a portion of the plurality of adjacent metal interconnects coupled to the bottom surface of the metal via; and
a dielectric protection layer between the bottom surface of the metal via and the first top surface of the first dielectric layer and co-extensive with the bottom surface of the metal via between the plurality of adjacent metal interconnects.

2. The semiconductor die of claim 1, wherein the dielectric protection layer is selected from a group consisting of silicon oxycarbide (SiOC), silicon nitride (SiN), and silicon carbon nitride (SiCN).

3. The semiconductor die of claim 1, wherein:
the conductive bridge comprises an outer sidewall extending in a vertical direction and defining a periphery of the conductive bridge;
the dielectric protection layer further extends in the horizontal direction on top of the first dielectric layer perpendicular to the outer sidewall and outside the periphery of the conductive bridge; and
the semiconductor die further comprises:
a high-K dielectric layer extending in the horizontal direction, perpendicular to the outer sidewall, and on top of the dielectric protection layer outside the periphery of the conductive bridge.

4. The semiconductor die of claim 3, wherein the high-K dielectric layer is selected from a group consisting of aluminum nitride (AIN) and aluminum oxide (Al₂O₃).

5. The semiconductor die of claim 3, further comprising:
a low-K dielectric layer extending in the horizontal direction, perpendicular to the outer sidewall, and on top of the high-K dielectric layer outside the periphery of the conductive bridge.

6. The semiconductor die of claim 1,
wherein the conductive bridge has a third top surface,
the semiconductor die further comprising:
a second metallization layer, comprising:
a metal interconnect extending in the horizontal direction on top of the third top surface of the conductive bridge.

7. The semiconductor die of claim 1, wherein the plurality of adjacent metal interconnects comprises two metal interconnects.

8. The semiconductor die of claim 3, wherein:
the high-K dielectric layer has a first etch rate and the dielectric protection layer has a second etch rate,
a ratio between the first etch rate and the second etch rate is equal to or greater than 5:1.

9. The semiconductor die of claim 1 integrated into a device selected from a group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics systems; and a multicopter.

10. A method of fabricating a semiconductor die, comprising:
forming a first metallization layer, comprising:
forming a first dielectric layer extending in a horizontal direction and having a first top surface; and
forming a first metal layer extending in the horizontal direction in the first dielectric layer, forming the first metal layer comprising:
forming a plurality of adjacent metal interconnects having a second top surface; and
forming a conductive bridge comprising:
forming a metal via having a bottom surface, comprising:
extending the metal via over the first top surface of the first dielectric layer between the plurality of adjacent metal interconnects; and
coupling the metal via to the second top surface of the plurality of adjacent metal interconnects;
coupling the bottom surface of the metal via to a portion of the plurality of adjacent metal interconnects; and
forming a dielectric protection layer between the bottom surface of the metal via and the first top surface of the first dielectric layer and co-extensive with the bottom surface of the metal via between the plurality of adjacent metal interconnects.

11. The method of claim 10, wherein the dielectric protection layer is selected from a group consisting of silicon oxycarbide (SiOC), silicon nitride (SiN), and silicon carbon nitride (SiCN).

12. The method of claim 10, wherein:
the conductive bridge comprises an outer sidewall extending in a vertical direction and defining a periphery of the conductive bridge;
the dielectric protection layer further extends in the horizontal direction on top of the first dielectric layer perpendicular to the outer sidewall and outside the periphery of the conductive bridge; and
the method further comprises:
forming a high-K dielectric layer extending in the horizontal direction, perpendicular to the outer sidewall, and on top of the dielectric protection layer outside the periphery of the conductive bridge.

13. The method of claim 12, wherein the high-K dielectric layer is selected from a group consisting of aluminum nitride (AIN) and aluminum oxide (Al₂O₃).

14. The method of claim 12, further comprising:
forming a low-K dielectric layer extending in the horizontal direction, perpendicular to the outer sidewall, and on top of the high-K dielectric layer outside the periphery of the conductive bridge.

15. The method of claim 10,
wherein the conductive bridge has a third top surface,
the method further comprising:
forming a second metallization layer, comprising:
forming a metal interconnect extending in the horizontal direction on top of the third top surface of the conductive bridge.
